(19) United States
(12) Patent Application Publication
(10) Pub. No.: US 2021/0184640 A1
(43) Pub. Date: Jun. 17, 2021

(54) DECISION FEEDBACK EQUALIZER CIRCUIT AND SEMICONDUCTOR INTEGRATED CIRCUIT THAT INCLUDES DECISION FEEDBACK EQUALIZER CIRCUIT

(71) Applicant: FUJITSU LIMITED, Kawasaki-shi (JP)

(72) Inventor: Yohei Miura, Kawasaki (JP)

(73) Assignee: FUJITSU LIMITED, Kawasaki-shi (JP)

(21) Appl. No.: 17/106,236

(22) Filed: Nov. 30, 2020

(30) Foreign Application Priority Data
Dec. 12, 2019 (JP) 2019-224620
Oct. 26, 2020 (JP) 2020-178584

(51) Int. Cl. H03F 3/45

(52) U.S. Cl. CPC H03F 3/45192; H03F 2203/45074; H03F 2203/45212; H03F 3/45206

(57) ABSTRACT

A decision feedback equalizer circuit includes first and second equalizers implemented in parallel. Each equalizer includes: an adder; and a comparator configured to alternatingly perform refreshing and sampling for a differential signal output from the adder. The comparator includes: a differential amplifier configured to output a differential signal having same values in a refresh period, and output a differential signal corresponding to the differential signal output from the adder in a sampling period; and a latch circuit configured to perform a decision operation based on a comparison between two signals that form the differential signal output from the differential amplifier, and to latch a decision result. The adder in the first equalizer controls the differential signal based on the decision in the second equalizer, and the adder in the second equalizer controls the differential signal based on the decision in the first equalizer.

### CROSS-REFERENCE TO RELATED APPLICATIONS

This application is based upon and claims the benefit of priority of the prior Japanese Patent Application No. 2019-224620, filed on Dec. 12, 2019, and the prior Japanese Patent Application No. 2020-178584, filed on Oct. 26, 2020, the entire contents of which are incorporated herein by reference.

### FIELD

The embodiments discussed herein are related to a decision feedback equalizer circuit and a semiconductor integrated circuit that includes the decision feedback equalizer circuit.

### BACKGROUND

In recent years, the performance of components such as the CPU that constitute information processing systems have improved. For this reason, a higher-speed communication circuit for conducting data transmission between components (that is, the interconnect circuit) required to improve the performance of information processing systems. Then, in many cases, communication circuits for conducting high-speed data transmission are equipped with an equalizer circuit (equalizer) that performs compensation for the degradation of signals that occurs in the communication path.

As an embodiment of an equalizer circuit that performs compensation for the degradation of signals, a decision feedback equalizer circuit (DFE: Decision Feedback Equalizer) has been known (for example, Japanese Laid-open Patent Publication No. 2011-244284, Japanese Laid-open Pat ant Publication No. 2017-229014, and Japanese Laid-open Patent Publication No. 2018-133760). The decision feedback equalizer circuit is equipped with, as illustrated in FIG, 1 for example, an adder 501, a comparator 502, and a feedback filter 503.

The adder 501 removes the output signal of the feedback filter 503 from a data signal Xk to generate a signal Yk. Here, the output signal of the feedback filter 503 represents the inter symbol interference (ISI) component of the data signal. Therefore, the signal Yk generated by the adder 501 represents the data signal in which compensation for the inter symbol interference has been performed. Then, the comparator 502 decides the value of the signal Yk. As a result, an equalized data signal Dk is obtained.

The feedback filter 503 has delay elements, multipliers, and a summing element. The respective delay elements delay the data signal Ek by a symbol time sequentially. The respective multipliers multiply the data signal Dk that is output from the corresponding delay element by a weight W (W1 through Wn). Each weight W is determined in advance by measurement, simulation or the like. Then, the summing element calculates the sum of the out but values of the respective multipliers. As a result, the inter signal interference component of the data signal Xk is obtained. Therefore, the decision feedback equalizer circuit, compensation for the degradation due to the inter signal interference is performed.

A configuration has been proposed in which the comparator alternately performs the sampling operation and the refresh operation to suppress the power consumption of the decision feedback equalizer circuit. However, when the comparator performs the refresh operation, the decision result by the comparator is lost. For this reason, in the configuration in which the comparator alternately performs the sampling operation and the refresh operation, a latch circuit that holds the result of decision by comparison is provided at the output side of the comparator. In this case, the output signal of the latch circuit is used as a feedback signal.

By the way, in order to equalize the data signal with a good accuracy, the feedback of the decided value needs to be performed within 1UI in decision feedback equalizer circuit. That is, it is required that the delay time of the decision, feedback equalizer circuit is 1UI or less.

However, in recent years, a higher speed is required for data signals. For example, when the data signal is 28 GBaud, 1UI is about 35.71 picoseconds. For this reason, it is becoming difficult to realize the decision feedback equalizer circuit. Particularly in the configuration in which a latch circuit is provided on the output side of the comparator, the delay time of the decision feedback equalizer circuit includes the operation time of the latch circuit, and therefore, it becomes further difficult to realize the decision feedback equalizer circuit.

Meanwhile, by adopting the speculative DFE scheme, the delay time of the decision feedback equalizer circuit is suppressed. However, when adopting the speculative DFE scheme, the power consumption of the decision feedback equalizer circuit becomes large.

### SUMMARY

According to an aspect of the embodiments, a decision feedback equalizer circuit equalizes a differential signal using a first equalizer circuit and a second equalizer circuit implemented in parallel. Each of the first equalizer circuit and the second equalizer circuit includes: an adder circuit; and a comparator configured to alternatingly perform refreshing and sampling for a differential signal output from the adder circuit in response to a clock signal. The respective comparator includes: a differential amplifier circuit configured to output a differential signal having same values in a refresh period in which the refreshing is performed, and output a differential signal corresponding the differential signal output from the adder circuit in sampling period in which the sampling is performed; and a latch circuit configured to perform a decision operation based on a comparison between a first signal and a second signal that form the differential signal output from the differential amplifier circuit in the sampling period, and to latch a decision result of the decision operation. The adder circuit in the first equalizer circuit controls a differential signal input to the decision feedback equalizer circuit based on the decision result latched by the latch circuit in the second equalizer circuit, and the adder circuit in the second equalizer circuit controls the differential signal input to the decision feedback equalizer circuit based on the decision result latched by the latch circuit in the first equalizer circuit.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an example of a decision feedback equalizer circuit;

FIG. 2 illustrates an example of decision feedback equalizer circuit that equalizes an input signal by time interleave;

FIG. 3 illustrates an example of the configuration of a comparator;

FIG. 4 illustrates an example of the operation of the comparator illustrated in FIG. 3;

FIG. 5 illustrates an example of a time-interleave operation by a pair of equalizer circuits;

FIG. 6 illustrates an example of a decision feedback equalizer circuit according to an embodiment of the present invention;

FIG. 7A and 7B illustrate examples of an adder circuit;

FIG. 8A and 8B illustrate examples of an adder circuit that includes a feedback filter;

FIG. 9 illustrates an example a decision feedback equalize circuit according to another embodiment;

FIG. 10 illustrates an example of the operation of the decision feedback equalizer circuit illustrated in FIG. 9;

FIG. 11A and 11B illustrate an example of a duty cycle adjustment circuit;

FIG. 12 illustrates another example of the configuration of a comparator;

FIG. 13 illustrates a configuration example of an adder circuit and a feedback filter; and

FIG. 14 illustrates an example of a semiconductor integrated circuit that includes a decision feedback equalizer circuit.

### DESCRIPTION OF EMBODIMENTS

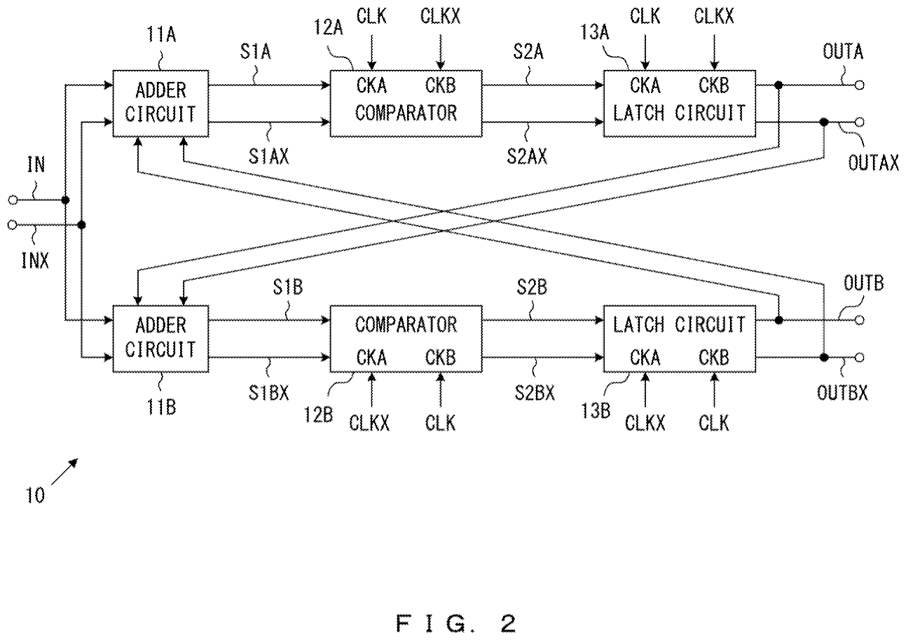

FIG. 2 illustrates an example of decision feedback equalizer circuit that equalizes an input signal by time interleave. The feedback equalizer circuit that equalizes an input signal by time interleave has a plurality of equalizer circuits that are provided in parallel to each other. In this example, a decision feedback equalizer circuit 10 is equipped with two equalizer circuits that are provided in parallel to each other. That is, the decision feedback equalizer circuit 10 is a half-rate decision feedback equalizer circuit.

One of the equalizer circuits is equipped with an adder circuit 11A, a comparator 12A, and the latch circuit 13A. The other equalizer circuit is equipped with an adder circuit 11B, a comparator 12B, and a latch circuit 13B. Then, a differential signal is input to the decision feedback equalizer circuit 10. In FIG. 2, “X” represents “inversion”. That is, a signal iX represents an inverted signal of a signal i. The differential signal is composed of a pair of signals that are inverse to each other. That is, the signal i and the signal iX form a differential signal.

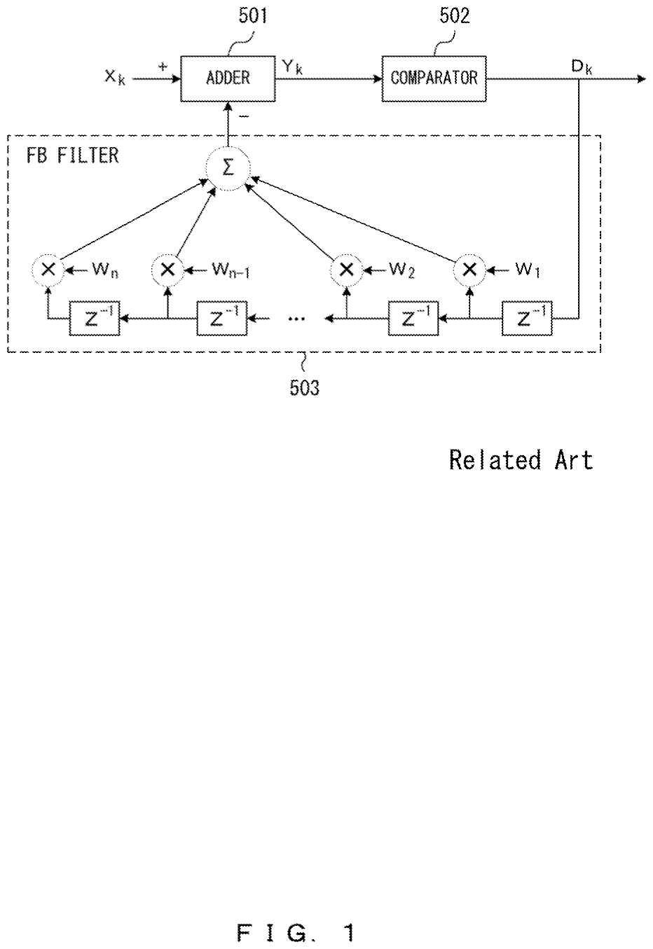

The adder circuit 11A corrects the input signals IN/INX using the signals OUTB/OUTBX that are output from the latch circuit 13B to generate the signals S1A/S1AX. The adder circuit 11A may correspond to the feedback filter 503 and the adder 501 illustrated in FIG. 1. In this case, the feedback filter 503 generates a feedback signal that represents the inter symbol interference component of the input signal according to the signals OUTB/OUTBX. Then, the adder 501 removes the feedback signal from the input signals IN/INX. As a result, compensation for the inter symbol interference is performed.

The comparator 12A performs a decision operation for the signals S1A/S1AX that are output from the adder circuit 11A in synchronization with the clock signals CLK/CLKX. At this time, the comparator 12A performs a decision operation based on the comparison of the signal S1A and the signal S1AX, to generate the signals S2A/S2AX that represent the result of the decision. As an example, when the signal S1A is higher than the, signal S1AX, “H (or, 1)” is output as the signal S2A, and “L (or, zero)” is output as the signal S2AX.

The latch circuit 13A latches the signals S2A/S2AX that are output from the comparator 12A in synchronization with the clock signals CLK/CLKX. Then, the latch circuit 13A outputs the latched signals as the signals OUTA/OUTAX.

The configurations and operations of the adder circuit 11B, the comparator 12B, and the latch circuit 13B are substantially the same as those of the adder circuit 11A, the comparator 12A, and the latch circuit 11A. However, the adder circuit 11B corrects the input signals IN/INX using the signals OUTA/OUTAX that are output from the latch circuit 13A.

In the decision feedback equalizer circuit 10 configured as described above, each of the comparators 12A and 12B performs a sampling operation and a refresh operation alternatingly in order to suppress the power consumption. In the sampling period, the decision for the input signal is performed, and the decision result is held. Meanwhile, in the refresh period, the decision result obtained during the sampling period is erased.

Here, when one of the equalizer circuits performs the sampling operation, the other equalizer circuit performs the refresh operation. That is, when the comparator 12A performs the sampling operation, the comparator 12B performs the refresh operation. Meanwhile, when the comparator 12A performs the refresh operation, the comparator 12B performs the sampling operation.

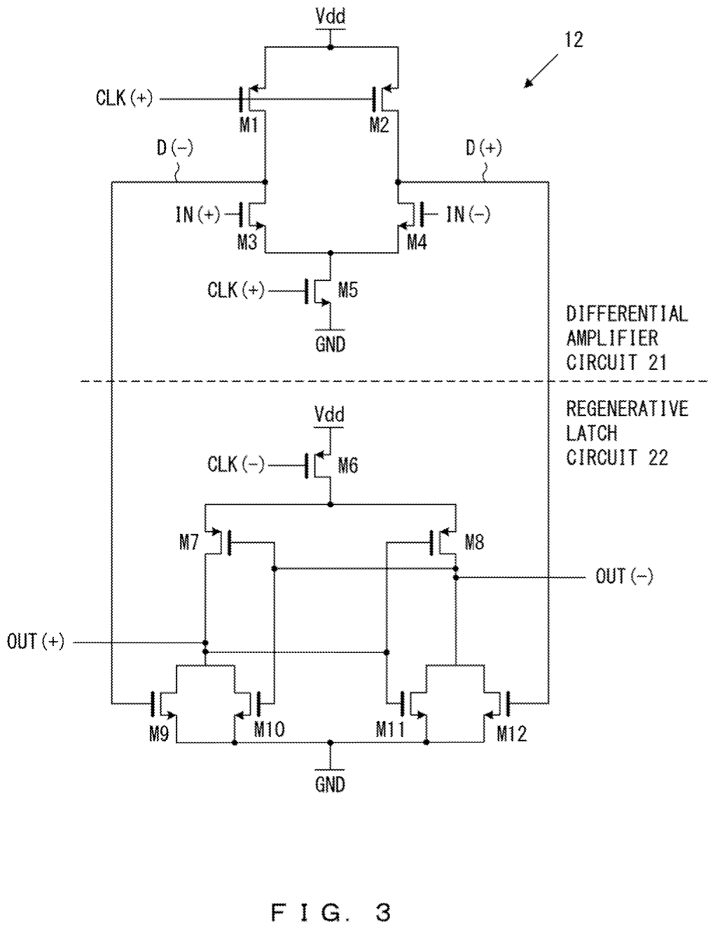

FIG. 3 illustrates an example u the configuration of the comparator. In this example, the comparator 12 (12A, 12B) is equipped with a differential amplifier circuit 21 and a regenerative latch circuit 22, as illustrated in FIG. 3. The comparator that decides the value of each symbol of the differential signal using the differential amplifier circuit 21 and the regenerative latch circuit 22 may be called a double-tall comparator.

In the descriptions below, the input signal IN is a differential signal and is composed of the signal IN(+) and the signal IN(−). The clock signal CLK is also a differential signal and is composed of the signal CLK(+) and the signal CLK(−).

The differential amplifier circuit 21 includes transistors M1 through M5. The transistors M1 and M2 are respectively a P-channel MOS transistor. The transistors M3 through M5 are respectively an N-channel MOS transistor.

The voltage Vdd is applied to sources of the transistors M1 and M2. The clock signal CLK(+) is given to gates of the transistors M1 and M2. Drains of the transistors M1 and M2 are connected to drains of the transistors M3 and M4, respectively. The input signal IN(+) is given to a gate of the transistor M3, and the input signal IN(−) is given to a gate of the transistor M4. Sources of the transistors M3 and M4 are respectively connected to a drain of the transistor M5. The clock signal CLK(+) is given to a gate of the transistor M5. A source of the transistor M5 is grounded.

The regenerative latch circuit includes transistors M6 through M12. The transistors M6 through M8 are respectively a P-channel MOS transistor. The transistors M9 through M12 are respectively an N-channel MOS transistor.

The voltage Vdd is applied to a source of the transistor M6 The clock signal CLK(−) is given to a gate of the transistor M6. A drain of the transistor M6 is connected to sources of the transistor M7 and M8. A gate of the transistor M7 is connected to a drain of the transistor M8, and a gate of the transistor M8 is connected to a drain of the transistor M7. A drain of the transistor M7 is connected to a drain of the transistor M9, a drain of the transistor M10, and a gate of the transistor M11. A drain of the transistor M8 is connected to a drain of the transistor M11, a drain of the transistor M12, and a gate of the transistor M10. A gate of the transistor M9 is connected to the drain of the transistor M1, and a gate of the transistor M12 is connected to the drain of the transistor M2. Sources of the transistors M9 through M12 are respectively grounded.

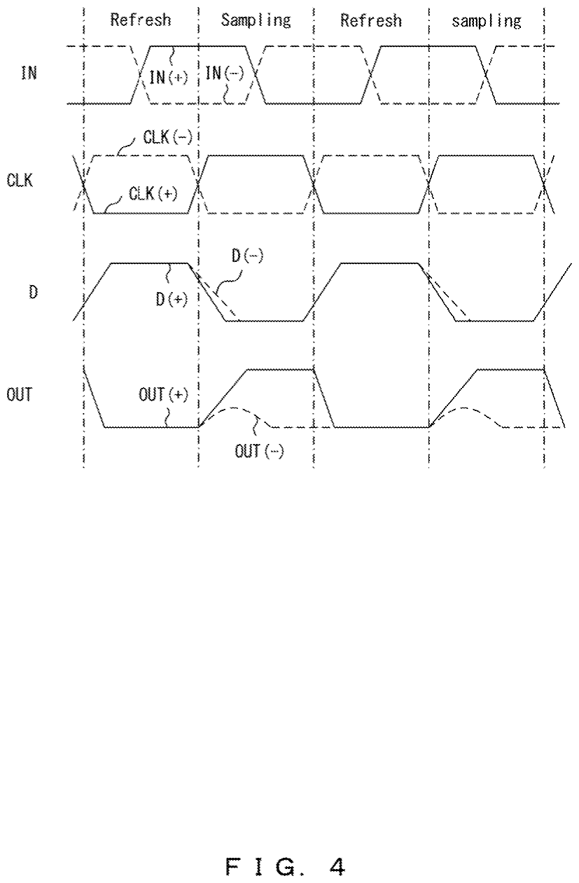

FIG. 4 illustrates an example of the operation of the comparator 12 illustrated in FIG. 3. The input data signal IN and the clock signal CLX are given to the comparator. Here, it is assumed that the clock signal CLK is adjusted so that the edge (rising edge/falling edge) of the clock signal CLK appears approximately at the center of each symbol period of the input data signal IN.

When the clock signal CLK(α) is L level, (or, when the clock signal CLK(−) is H level), the comparator 12 performs the refresh operation. That is, during the period in which the clock signal CLK(+) is L level, the transistors M1 and M2 are controlled to the ON state, and the transistor M5 is controlled to the OFF state. Therefore, the signal D(+) and the signal D(−) that are output from the differential amplifier circuit 21 are both held at Vdd. When the signal D(+) and the signal D(−) are held at Vdd, the transistors M9 and M12 are respectively controlled to the ON state. Then the signal OUT(+) and the signal OUT(−) that are output from the comparator 12 are both held at the GND level. That is, the regenerative latch circuit 22 is refreshed.

When the clock signal CLK(+) changes from L level to H level (or, the clock signal CLK(+) changes from H level to L level), the comparator 12 starts the sampling operation. That is, during the period in which the clock signal CLK(+) is H level, the transistors M1 and M2 are controlled to the OFF state, and the transistor M5 is to the ON state. Therefore, the signal D(+) and the signal D(−) that are output from the differential amplifier circuit 21 respectively change from Vdd toward GND level. At this time, the speed of the change of the signal DC(+) and the signal D(−) depends on the input data signal IN. Specifically, the speed of the change of the signal D(+) depends on the signal IN(−), and the speed of the change of the signal D(−) depends on the signal IN(+). In the example illustrated in FIG. 4, the signal D(+) falls to GND earlier than the signal D(−). In this case, it follows that the signal OUT(+) is held at H level, and the signal OUT(−) is held at the L level.

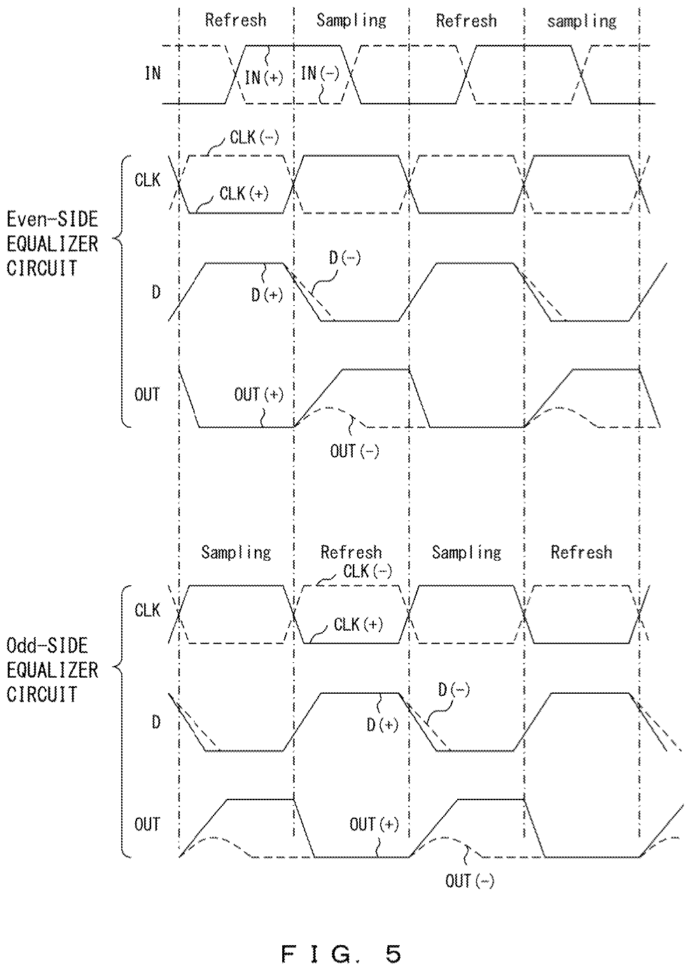

FIG. 5 illustrates an example of a time interleave operation by a pair of equalizer circuits. In the descriptions below, one of the pair of the equalizer circuits may be referred to as an “Even-side equalizer circuit”, and the other may be referred to as an “Odd-side equalizer circuit”.

The phase of the clock signal given to the Even-side equalizer circuit and the phase of the clock signal given to the Odd-side equalizer circuit are inverse to each other. Therefore, when the Even-side equalizer circuit performs the sampling operation, the Odd-side equalizer circuit performs the refresh operation. Meanwhile, when the Even-side equalizer circuit performs the refresh operation, the Odd-side equalizer circuit performs the sampling operation.

Therefore, the decision feedback equalizer circuit equipped with a pair of equalizer circuits alternatingly outputs the decision result of the Even-side equalizer circuit and the decision result of the Odd-side equalizer circuit. Specifically, when the Even-side equalizer circuit performs the refresh operation, the decision feedback equalizer circuit outputs the decision result of the Odd-side equalizer circuit. On the other hand, when the Odd-side equalizer circuit performs the refresh operation, the decision feedback equalizer circuit outputs the result of the operation of the Even-side equalizer circuit. Accordingly, in the configuration in which the respective equalizer circuits alternatingly perform the sampling operation and the refresh operation, the decision feedback equalizer circuit is able to equalize all symbols.

By the way, in order to equalize data signals with a good accuracy, the delay time of the decision feedback equalizer circuit is required to be 1UI or less. That is, it is required that the delay of the decision feedback equalizer circuit is 1UI or less.

However, in the configuration illustrated in FIG. 2, the decided values obtained by the comparator 12A and 12B are stored in the latch circuits 13A and 13B, and after that, the feedback from the latch circuits 13A and 13B to the adder circuits 11B and 11A is performed. For this reason, the delay time of the decision feedback equalizer circuit 10 becomes longer. That is, when the symbol rate of the data signal is high, it becomes difficult to make the delay time of the decision feedback equalizer circuit 10 1UI or less with the configuration illustrated in FIG. 2.

### Embodiment

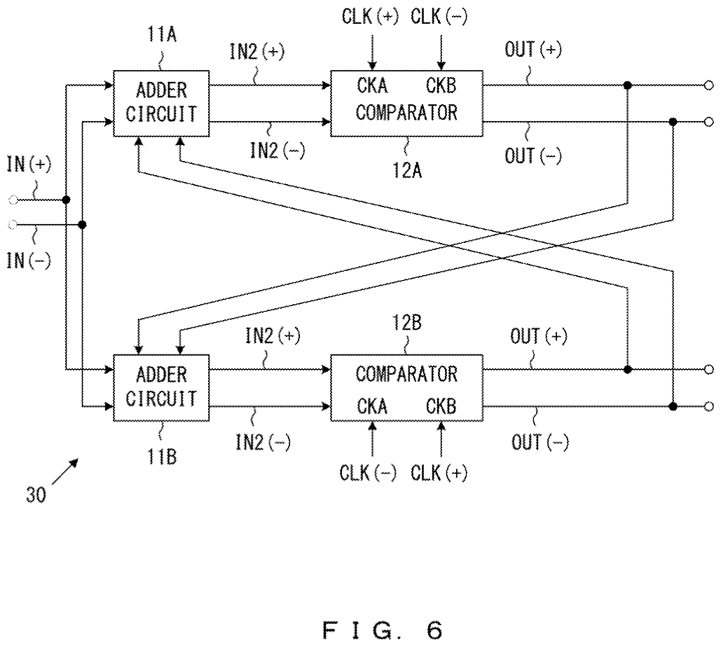

FIG. 6 illustrates an example of a decision feedback equalizer circuit according to an embodiment of the present invention decision feedback equalizer circuit 30 according to an embodiment of the present invention is equipped with a pair of equalizer circuits to realize half-rate time interleave. One of the equalizer circuits is equipped with an adder circuit 11A and a comparator 12A, and the other equalizer circuit is equipped with an adder circuit 11B and a comparator 12B. The pair of the equalizer circuits corresponds to the. Even-side equalizer circuit and the Odd-side equalizer in the example illustrated in FIG. 5.

The decision feedback equalizer circuit. 30 equalizes the input data signal IN. The input data signal IN is a differential signal and is composed of the signal IN(+) and the signal IN(−). In addition, the clock signal CLK is given to the decision feedback equalizer circuit 30. The clock signal CLK is a differential signal and is composed of the signal CLK(+) and the signal CLK(−). Then, the decision feedback equalizer circuit 30 outputs the signal OUT. The signal OUT is a differential signal and is composed of the signal OUT(+) and the signal OUT(−). Meanwhile, the signal OUT represents an equalized data signal. In addition, the decision feedback equalizer circuit 30 performs a time-interleave operation. That is, the signal OUT that is output from the comparator 12A and the signal OUT that is output from the comparator 12B are alternatingly used.

The adder circuit 11A corrects the input signal IN using the signal OUT that is output the comparator 12B to generate a signal IN2. The signal IN2 is a differential signal and is composed of the signal IN2(+) and the signal IN2(−). Here, the adder circuit 11A generates a feedback signal that represents the inter symbol interference component according to the signal OUT that is output from the comparator 12B. Then, the adder circuit 11A removes the feedback signal from the input signal IN to generate the signal IN2. As a result, compensation of the inter symbol interference is performed.

The comparator 12A performs a decision operation for the signal IN2 that is output from the adder circuit 11A, in synchronization with the clock signal CLK. Specifically, the comparator 12A performs a decision operation based on the comparison of the signal IN2(+) and the signal IN2(−) and outputs the signal OUT that represents the result of the decision. At this time, for example, when the signal IN2(+) is higher than the signal IN(−) , “H (or, 1)” is output as the signal OUT(+), and “L (or, zero)” is output as the signal OUT(−).

The comparator 12A realized by the circuit illustrated in FIG. 3, for example. That is, the comparator 12A is realized by a double-tail comparator that is equipped with the differential amplifier circuit 21 and the regenerative latch circuit 22. Meanwhile, the signal IN2(+) and the signal IN2(−) illustrated in FIG. 6 correspond to the signal IN(+) and the signal IN(−) in the example illustrated in FIG. 3.

The configurations and operations of the adder circuit 11B and the comparator 12B are substantially the same as those of the adder circuit 11A and the comparator 12A. That is, the adder circuit 11B and the comparator 12B also equalize the input signal IN and outputs the signal OUT. However, the phase of the clock signal given to the comparator 12A and the phase of the clock signal given to the comparator 12B are inverse to each other. Therefore, when the comparator 12A performs the sampling operation, the comparator 12B performs the refresh operation. Meanwhile, when the comparator 12A performs the refresh operation, the comparator 12B performs the sampling operation. Accordingly, the time interleave illustrated in FIG. 5 is realized.

Thus, the decision feedback equalizer circuit 30 according to an embodiment of the present invention is not equipped with the latch circuits 13A and 13B compared to the configuration illustrated in FIG. 2. For this reason, compared to the decision feedback equalizer circuit 10 illustrated in FIG. 2, the delay time of the decision feedback equalizer circuit 30 becomes small. Specifically, the delay time of the decision feedback equalizer circuit 30 becomes smaller by the operation time of the latch circuits 13A and 13B, compared to the configuration illustrated in FIG. 2.

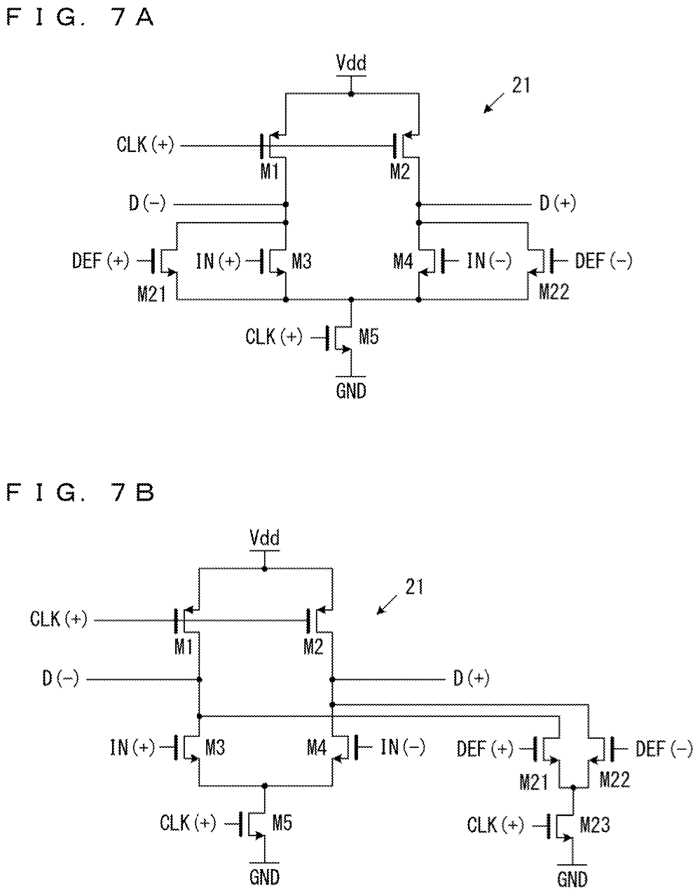

FIG. 7A and 7B illustrate examples of the adder circuit (11A, 11B). In the example illustrated in FIG. 7A, the adder circuit is realized by the transistor M21 and the transistor M22. The adder circuit is connected to the differential amplifier circuit 21 in the comparator 12 as illustrated in FIG. 3. Specifically, the transistor M21 is connected in parallel to the transistor M3, and the transistor M22 is connected in parallel to the transistor M4. The signal DEF given to the gate of the transistors M21 and M22 is a feedback signal that represents the inter symbol interference component in this example and is generated based on the signal OUT. Specifically, the feedback signals D(+) and D(−) that are generated based on the signal OUT output from the comparator 12B are fed to the transistors M21 and M22 in the adder circuit 11A. Similarly, the feedback signals D(+) and D(−) that are generated based on the signal OUT output from the comparator 12A are fed to the transistors M21 and M22 in the adder circuit 11B. Note that the signal D(+) is generated according to the signal IN(−) and the signal DEF(−). The signal is generated according to the signal IN(+) an the signal DEF(+).

In the configuration illustrated in FIG. 7A, the adder circuit (M21 and M22) and the differential amplifier circuit 21 share the current source transistor (that is, the transistor M5). In comparison to this, in the example illustrated in FIG. 7B, apart from the current source transistor (that is, the transistor M5) for the differential amplifier circuit 21, a current source transistor (that is, the transistor M23) for the adder circuit (M21 and M22) is provided. Note that the operation of the adder circuit is substantially the same in FIG. 7A and FIG. 7B.

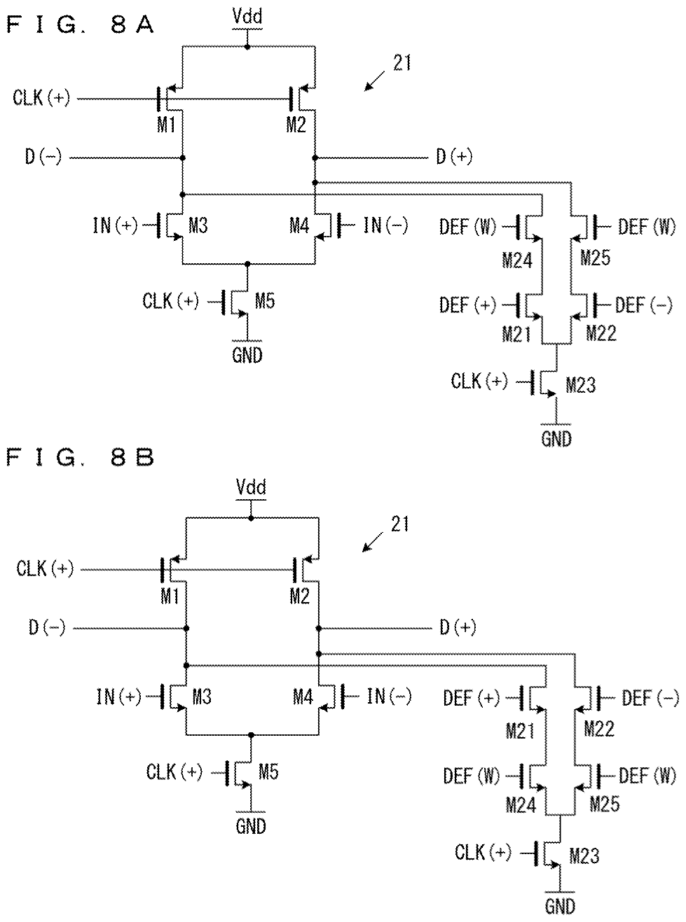

FIG. 8A and 8B illustrate examples of the adder circuit (11A, 11B) that includes a feedback filter. Note that, in this example, it is assumed that the adder circuit performs compensation tor the inter symbol interference caused by the immediately preceding symbol.

In the example illustrated in FIG. 8A, the adder circuit is realized by the transistors through M25. The transistor M21 through M23 are substantially the same in FIG. 3 and FIG. 8A. However, in FIG. 8A, the decision result obtained by the comparator (12B, 12A) of the other equalizer circuit is given to the gate of the transistors M21 and M22. The result of the decision represents “B (or, 1)” or “L (or, zero)”.

The transistors M24 and M25 are provided between the differential amplifier circuit 21 and the transistors M21 and M22. A weight signal DEF(W) is given to the respective gate of the transistors M24 and M25. Therefore, the current that flows via the transistors M21 and M22 is adjusted by the weight signal DEF(W). That is, the transistors M21 through M25 correspond to the adder 501 and the feedback filter 503 illustrated in FIG. 1. In this case, the weight signal DEB(W) corresponds to the weight W1 illustrated in FIG. 1. Note that in the configuration illustrated in FIG. 1, the signal Dk is multiplied by the weight W after delayed by the delay element Z. On the contrary, according to the present embodiment, the signal OUT (the signal DEF (+) and DEF(−) in FIG. 8) that indicates a result of decision for an immediately previous symbol of a target symbol may be fed directly to the transistors M21 and M22 without being delayed by the delay element.

The adder circuit that includes the feedback filter is not limited to the configuration illustrated in FIG. 8A. For example, as illustrated in FIG. 8B, the transistors M24 and M25 that performs weighting may be provided between the transistors M21 and M22 that operates as the adder and the transistor M23 that operates as the current source. Note that the operations of the circuit are substantially the same in FIG. 8A and FIG. 8B.

As described above, the decision feedback equalizer circuit 30 according to an embodiment of the present invention is not equipped with the latch circuits 13A and 13B illustrated in FIG. 2. For this reason, compared to the configuration illustrated in FIG. 2, the delay time of the decision feedback equalizer circuit becomes small. That is, in the decision feedback equalizer circuit 30, compared to the configuration illustrated in FIG. 2, the delay time becomes smaller by the operation time of the latch circuit 13A and 13B. However, in the case in which the time interleave operation is performed without providing the latch circuit (in the example illustrated in FIG. 2, the latch circuit 13A, 13B) on the output side of the comparators 12A, and 12B, the decision feedback equalizer circuit may not be able to perform compensation of the inter symbol. interference with a good accuracy in some cases. The reason for this is as described below.

In the decision feedback equalizer circuit 30 illustrated in FIG. 6, one of the equalizer circuits (for example, the Even-side equalizer circuit illustrated in FIG. 5) performs compensation for the inter symbol interference of the input signal IN using the output signal OUT of the other equalizer circuit (for example, the Odd-side equalizer circuit illustrated in FIG. 5). Therefore, for example, when the Even-side equalizer circuit performs compensation for the inter symbol interference of the input signal IN, it is preferable that the signal OUT is held at the Odd-side equalizer circuit. Here, the output signal OUT that represents the decision result is held during the sampling period in which the comparator performs the sampling operation. However, in the configuration in the Even-side equalizer circuit and the Odd-side equalizer circuit alternatingly perform the sampling operation, when the sampling period starts at the Even-side equalizer circuit, the refresh period starts at the Odd-side equalizer circuit. That is, when the Even-side equalizer circuit performs compensation for the inter symbol interference of the input signal IN, the output signal OUT that represents the decision result may not be held in the Odd-side equalizer circuit in some cases. As a result, the decision feedback equalizer circuit may not be able to perform compensation for the inter symbol interference with a good accuracy.

Therefore, the decision feedback equalizer circuit 30 according to the embodiments of the present invention is equipped with a function to resolve or alleviate the problem described above. The function is described below.

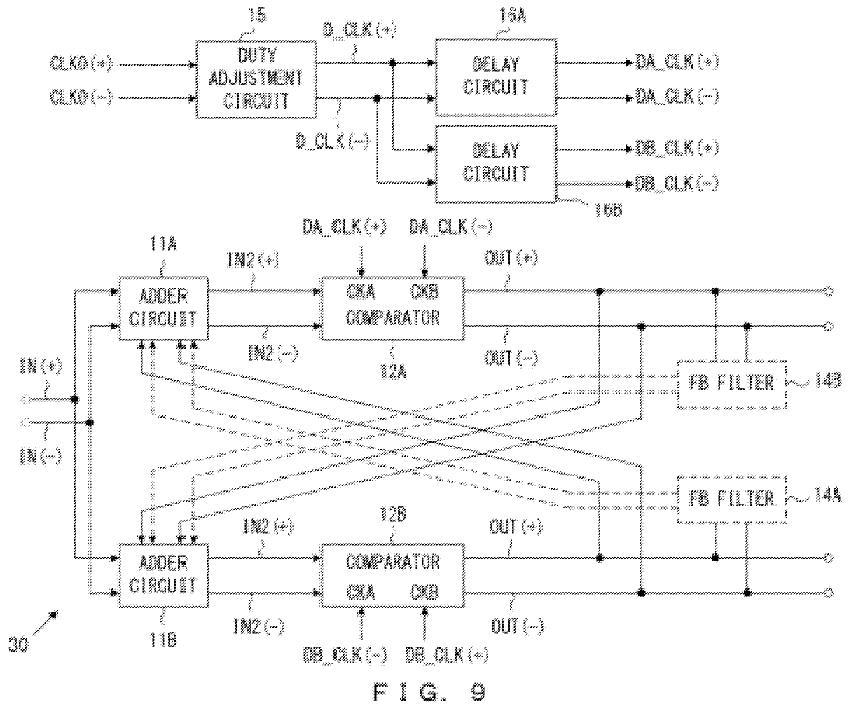

FIG. 9 illustrates an example of a decision feedback equalizer circuit according to another embodiment. In this embodiment, the decision feedback equalizer circuit 30 is equipped with a duty cycle adjustment circuit 15, the delay circuit 16A, and a delay circuit 16B, in addition to the configuration illustrated in FIG. 6. Note that the feedback filters 14A and 14B will be described later.

The duty cycle adjustment circuit 15 adjust the duty ratio of a clock signal CLK0 generated by a clock generator that is not illustrated in the drawing. Hare, the clock signal CLK0 is a differential signal and is composed of the signal CLK0(+) and the signal CLK0(−). In addition, it is assumed that the duty of the clock signal CLK0 is 50 percent. Then, the duty cycle adjustment circuit 15 outputs a clock signal D_CLK whose duty ratio has been adjusted. The clock signal D_CLK is a differential signal and is composed of the signal D_CLK(+) and the signal D_CLK(−).

The delay circuit 16A adjusts the phase of the clock signal D_CLK that is output from the duty cycle adjustment circuit 15. Then, a clock signal DA_CLK that is output from the delay circuit 16A is given to the comparator 12A. The clock signal DA_CLK is a differential signal and is composed of the signal DA_CLK(+) and the signal DA_CLK(−). The delay circuit 16B also adjusts the phase of the clock signal D_CLK that is output from the duty cycle adjustment circuit 15. However, a clock signal DB_CLK that is output from delay circuit 16B is given to the comparator 12B. The clock signal DB_CLK is a differential signal and is composed of the signal DB_CLK(+) and the signal DB_CLK(−).

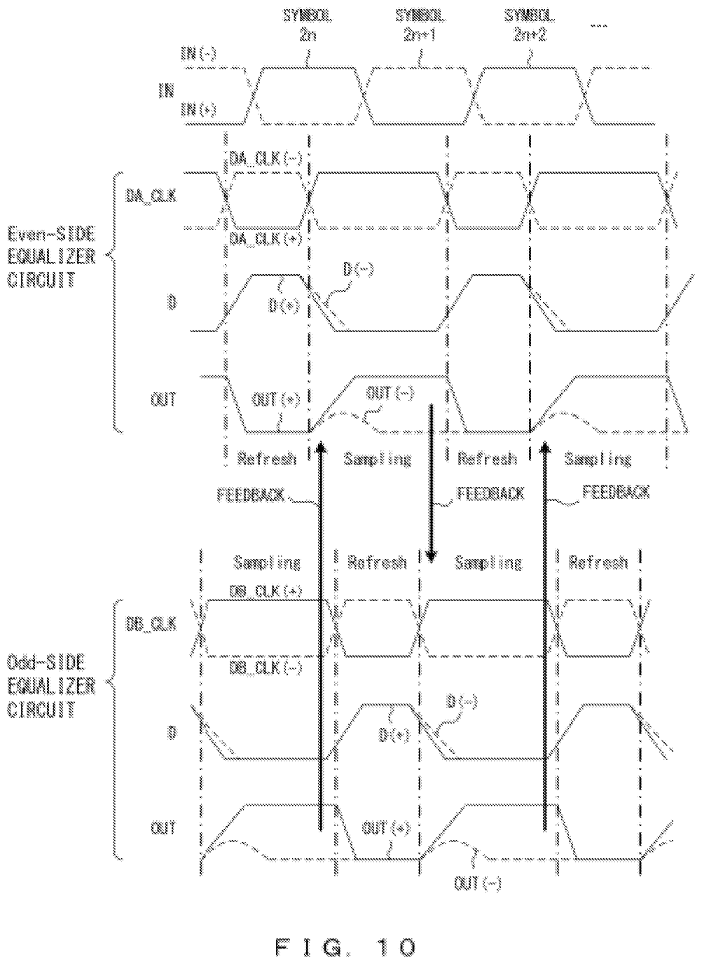

The delay circuits 16A and 16B respectively adjust the phase of the clock signal so as to realize the timing illustrated in FIG. 10 described later, for example. In this case, the delay circuits 16A and 16B may adjust the phase of the clock signal according to the output signal of the decision feedback equalizer circuit 30. Alternatively, the delay circuits 16A and 16B may be realized by wiring that propagates the clock signal.

FIG. 10 illustrates an example of the operation of the decision feedback equalizer circuit 30 illustrated in FIG. 9. It is assumed that the Even-side equalizer circuit corresponds to the adder circuit 11A and the comparator 12A illustrated in FIG. 9, and the Odd-side equalizer circuit corresponds to the adder circuit 11B and the comparator 12B. That is, the clock signal DA_CLK is given to the Even-side equalizer circuit, and the clock signal DB_CLK is given to the Odd-side equalizer circuit.

The Even-side equalizer circuit performs the refresh operation when the clock signal DA_CLK(+) is L level and performs the sampling operation when the clock signal DA_CLK(+) is H level. That is, the sampling period starts at the rising edge of the clock signal DA_CLK(+) changing from L level to H level. Meanwhile, it is assumed that, in the Even-side equalizer circuit, the timing of the clock signal DA_CLK is adjusted so that the start timing of the sampling period (that is, the rising edge of the clock signal DA_CLK(+)) appears approximately at the center of the symbol period of the input signal. As an example, the timing of the clock signal DA_CLK is adjusted so that the rising edge of the clock signal DA_CLK(+) appears approximately at the center of the even-numbered symbol of the input signal IN.

On the other hand, the Odd-side equalizer circuit performs the refresh operation when the clock signal DB_CLK(+) is L level and performs the sampling operation when the clock signal DB_CLK(+) is H level. That is, the sampling period starts at the rising edge of the clock signal DB_CLK(+) changing from L level to H level. In addition, in the Odd-side equalizer circuit, it is also assumed that the timing of the clock signal DB_CLK is adjusted so that the start timing of the sampling period (that is, the rising edge of the clock signal DB_CLK(+)) appears approximately at the center of the symbol period of the input signal IN. As an example, the timing of the clock signal DB_CLK is adjusted so that the rising edge of the clock signal DB_CLK(+) appears approximately at the center of the odd-numbered symbol of the input signal IN.

As described above, the Even-side equalizer circuit and the Odd-side equalizer circuit alternatingly equalizes the symbol string of the input signal IN. At this time, the decision result obtained by one of the equalizer circuits is fed back to the other equalizer circuit.

For example, when a symbol 2n is input to the decision feedback equalizer circuit 30, the Even-side equalizer circuit performs the sampling operation, and the decision result for that is stored in the regenerative latch circuit 22 in the comparator 12A. Note that an example of the regenerative latch circuit 22 is illustrated in FIG. 3. Next, when a symbol 2n+1 is input to the decision feedback equalizer circuit 30, the Odd-side equalizer circuit performs the sampling operation. At this time, the Odd-side equalizer circuit performs compensation for the inter symbol interference using the decision result for the symbol 2n. That is, the Odd-side equalizer circuit receives the decision result for the symbol 2n stored in the Even-side equalizer circuit as a feedback signal for performing compensation for the inter symbol interference. Here, when the sampling operation for the symbol 2n+1 starts in the Odd-side equalizer circuit, the sampling period for the symbol 2n is continued in the Even-side equalizer circuit. That is, when the sampling operation for the symbol 2n+1 starts in the Odd-side equalizer circuit, the decision result for the symbol 2n is stored without being refreshed in the Even-side equalizer circuit. Therefore, the Odd-side equalizer circuit is able to realize equalization with a good accuracy for the symbol 2n+1, using the decision result, for the symbol 2n.

When a symbol 2n+2 is input to the decision feedback equalizer circuit 30, the Even-side equalizer circuit performs the sampling operation. At this time, the Even-side equalizer circuit performs compensation for the inter symbol interference using the decision result for the symbol 2n+1. That is, the Even-side equalizer circuit receives the decision result for the symbol 2n+1 stored in the Odd-side equalizer circuit as a feedback signal for performing compensation for the inter symbol interference. Here, when the sampling operation for the symbol 2n+2 starts in the Even-side equalizer circuit, the sampling period for the symbol 2n+1 is continued in the Odd-side equalizer circuit. That is, when the sampling operation for the symbol 2n+2 starts in the Even-side equalizer circuit, the decision result for the symbol 2n+1 is stored without being refreshed in the Odd-side equalizer circuit. Therefore, the Even-side equalizer circuit is able to realize equalization with a good accuracy for the symbol 2n+2, using the decision result for the symbol 2n+1.

According to the embodiments, a duty ratio and a phase of the clock signal is adjusted such that the sampling period is longer than the refresh period. Thus, when the sampling operation for a target symbol starts in one of the equalizer circuits, the decision result for an immediately previous symbol is still stored without being refreshed in the other equalizer circuit. Therefore, the decision feedback equalizer circuit 30 can obtain the inter symbol interference component with respect to the target symbol. That is to say, the decision feedback equalizer circuit 30 can remove the inter symbol interference component from the target symbol.

The duty-adjusted clock signal may be given to the Even-side equalizer circuit and the Odd-side equalizer circuit so that the sampling period starts in the Odd-side equalizer circuit before the sampling period ends in the Even-side equalizer circuit, and the sampling period starts in the Even-side equalizer circuit before the sampling period ends in the Odd-side equalizer circuit. In addition, a timing or a phase of the duty-adjusted clock signal may be adjusted so that, in the comparator 12A implemented in the Even-side equalizer circuit, a timing of a change of the duty-adjusted clock signal from the first state to the second state appears approximately at a center of an even-numbered symbol of the input differential signal of the decision feedback equalizer circuit, and in the comparator 12B implemented in the Odd-side equalizer circuit, a timing of a change of the duty-adjusted clock signal from the first state to the second state appears approximately at a center of an odd-numbered symbol of the input differential signal of the decision feedback equalizer circuit.

Thus, the decision feedback equalizer circuit 30 is able to equalize the input data signal with a good accuracy by adjusting the duty ratio of the clock signal. Specifically, since the duty ratio of the clock signal is adjusted such that a duration of the sampling period is longer that a duration of the refresh period, when one of the equalizer circuits starts the sampling operation, the refresh operation does not yet start in the other equalizer circuit. That is to say, when one of the equalizer circuits starts the sampling operation, a result of a decision by the other equalizer, circuit is preserved without being refreshed. Thus, the input data signal is equalized by using an accurate feedback signal. Here, the decision feedback equalizer circuit 30 is not equipped with the latch circuit at the output side of the comparators 12A and 12B. Therefore, the delay time of the decision feedback equalizer circuit 30 becomes small, and therefore, it is possible to equalize a data signal of a broader bandwidth.

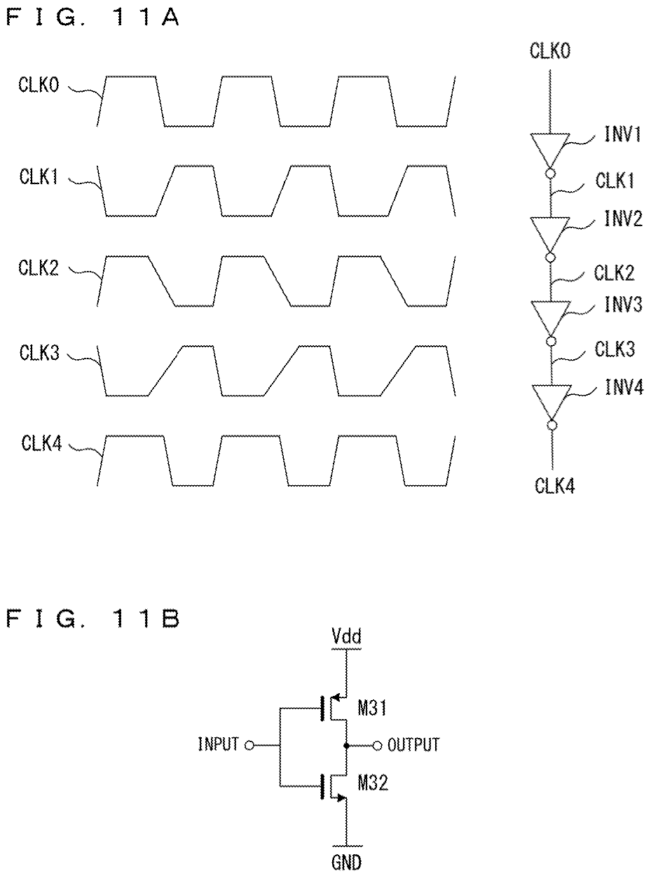

FIG. 11A and 11B illustrate an example of the duty cycle adjustment circuit 15. The duty cycle adjustment circuit 15 is realized by a plurality of inverters connected in serial, for example. In the example illustrated in FIG. 11A, the duty cycle adjustment circuit 15 includes inverters INV1 through. INV4. Each inverter is composed of a PMOS transistor M31 and an NMOS transistor M32, for example, as illustrated in FIG. 11B. Then, a clock signal CLK0 is input to the inverter INV1. The duty ratio of the clock signal CLK0 is 50 percent.

In the duty cycle adjustment circuit 15, an inverter whose PMOS transistor M31 is smaller than NMOS transistor M32 in size and an inverter whose NMOS transistor M32 is smaller than the PMOS transistor M31 in size are alternatingly arranged. In FIG. 11A, the PMOS transistor M31 is smaller than NMOS transistor M32 in size in the inverters INV1, INV3. Meanwhile, the NMOS transistor M32 is smaller than the PMOS transistor M31 in size in the inverter INV2. Meanwhile, in the inverters whose PMOS transistor M31 is smaller than NMOS transistor M32 in size (that is, the inverters INV1, INV3), the rising edge of the output signal becomes moderate. On the other hand, in the inverter whose NMOS transistor M32 is smaller than the PMOS transistor M31 in size (that is, the inverter INV2), the falling edge of the output signal becomes moderate.

Then, in the inverter at the last stage (that is, the inverter 4), the size of the PMOS transistor M31 and the size of the NMOS transistor M32 are the same as each other. With this configuration, a clock signal CLK4 whose duty ratio has been adjusted is obtained. Note that it is possible to obtain a clock signal that has the desired duty ratio may be obtained by adjusting the number of stages of inverters connected in parallel and/or the size ratio of the PMOS transistor M31 and the NMOS transistor M32 in each inverter.

In the embodiments, when the duty ratio of the block signal is adjusted as explained with reference to FIG. through FIG. 11B., the refresh period becomes shorter compared to the configuration in which the duty ratio of the clock signal is 50 percent. Then, when the refresh period becomes shorter, it becomes difficult for the regenerative latch circuit 22 to be sufficiently refreshed. Therefore, the decision feedback equalizer circuit 30 is equipped with a function to solve or alleviate this problem.

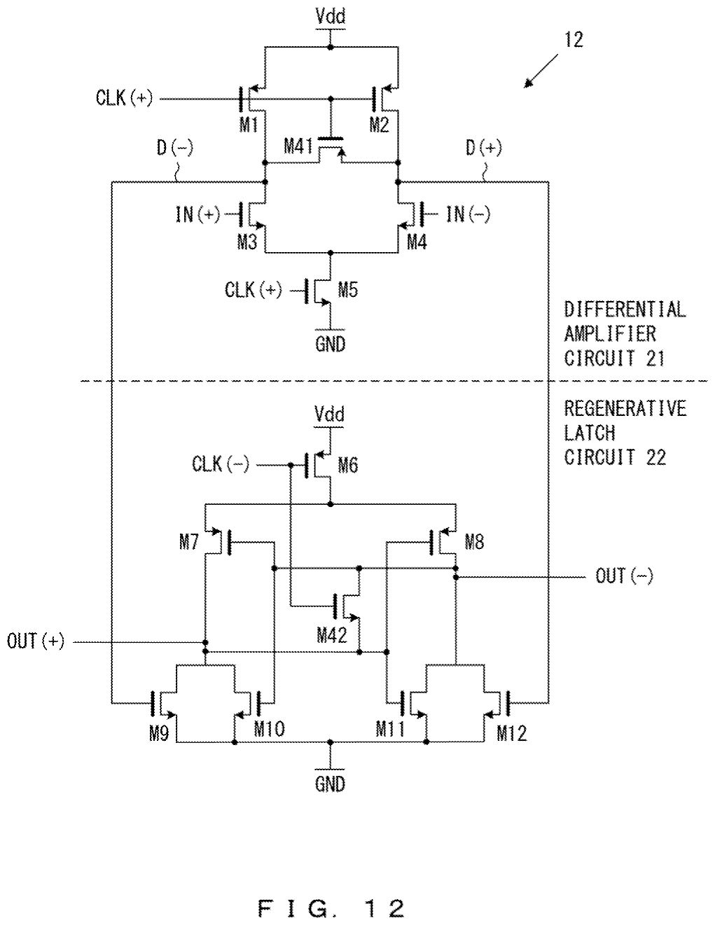

FIG. 12 illustrates another example of the configuration of a comparator. The comparator is equipped a transistor M41 and a transistor M42, in addition to the circuit illustrated in FIG. 3.

The transistor M41 is a P-channel MOS transistor. A clock signal CLK(+) is given to the gate of the transistor M41. The drain and the source of the transistor M41 are connected to the drain of the transistor M1 and the drain of the transistor M2, respectively.

The transistor M42 is an N-channel MOS transistor. A clock signal CLK(−) is given to the gate of the transistor M42. The drain and the source of the transistor M42 are connected to the drain of the transistor M8 and the drain of the transistor M7, respectively.

In the comparator illustrated in FIG. 12, when the clock signal CLK(+) changes from H level to L level and the clock signal CLK(−) changes from L level to H level, the transistor M41 and the transistor M42 are controlled from the OFF state to the ON state. That is, at the start of the refresh period, the transistor M41 is controlled to the ON state, the pair of the output wirings of the differential amplifier circuit 21 are shorted. That is, immediately after the start of the refresh period, the wiring that propagates the signal D(+) and the wiring that propagates the signal D(−) are shorted, the signal D(+) and the signal D(−) are forcedly controlled to H level. Then, when the signal D(+) and the signal D(−) are controlled to H level, the transistor M9 and the transistor M12 axe controlled to the ON state, and the regenerative latch circuit 22 is refreshed.

In addition, when the transistor M42 is controlled to the ON state at the start of the refresh period, the pair of the output wirings of the regenerative latch circuit 22 are shorted. That is, immediately after the start of the refresh period, the wiring that outputs the signal OUT(+) and the wiring that outputs the signal OUT(−) are shorted, and the regenerative latch circuit 22 is refreshed.

As described above, according to the configuration illustrated in FIG. 12, immediately after a start of the refresh period, the regenerative latch circuit 22 is refreshed. Therefore, even in the configuration in which the refresh period becomes shorter due to the adjustment of the duty ratio of the clock signal, the regenerative latch circuit 22 is certainly refreshed. Therefore, the negative effect on the judgment in the next sampling period is suppressed.

In FIG. 12, the transistor M41 is provided in the differential amplifier circuit 21, and the transistor M42 is provided in the regenerative latch circuit 22, but the present invention is not limited to this configuration For example, either the transistor M41 or the transistor M42 may be omitted.

The decision feedback equalizer circuit 30 illustrated in FIG. 6 or FIG. 9 may be equipped with the latch circuit respectively at the output side of the comparator 12A and 12B. However, even in such a case, in the decision feedback equalizer circuit 30 according to the present invention, the decision results respectively latched in the comparators 12A and 12B (or, the output signal of the comparators 12A and 12B) are fed back to the adder circuits 11A, 11B.

Note that in the embodiments described above, the equalizer circuit compensates for an inter symbol interference caused by one symbol immediately previous of a target symbol for simple description. However, in order to improve an accuracy of equalization, it is preferable to compensate for the inter symbol interference by using a plurality of symbols. Therefore, the decision feedback equalizer circuit 30 may be equipped with the feedback filters 14A and 14B, as illustrated in FIG. 9.

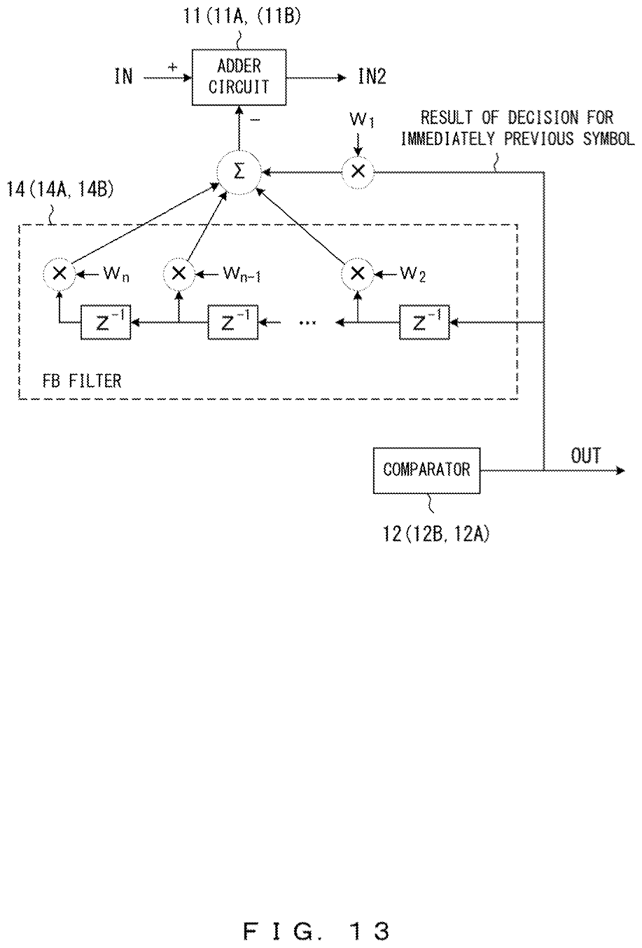

FIG. 13 illustrates a configuration example of an adder circuit and a feedback filter, in this example, the decision feedback equalizer circuit 30 is n-tap configuration. That is, the adder circuit 11 compensates for the input signal by using n symbols immediately previous of a target symbol.

Here, in order to realize an accurate decision feedback equalization, it is preferable that a result of a decision for an immediately previous symbol by one of the equalizer circuits is provided before the other equalizer circuit starts the decision operation. However, in recent years, the symbol rate is very high. Thus, the decision result OUT for an immediately previous symbol of the target symbol is fed to the adder circuit 11 without being delayed by the delay element in the example in FIG. 13. At this tame, the decision result is multiplied by the weight W1. On the other hand, the decision results for n-1 symbols located between second previous symbol through n-th previous symbol with respect to the target symbol are sequentially delayed by one symbol period. At this time, the feedback filter 14 multiplies the decision results for the n-1 symbols respectively may the weights W2 through Wn. By doing this, the feedback signal corresponding to the n symbols is generated. Then the adder circuit 11 removes the feedback signal from the input signal IN.

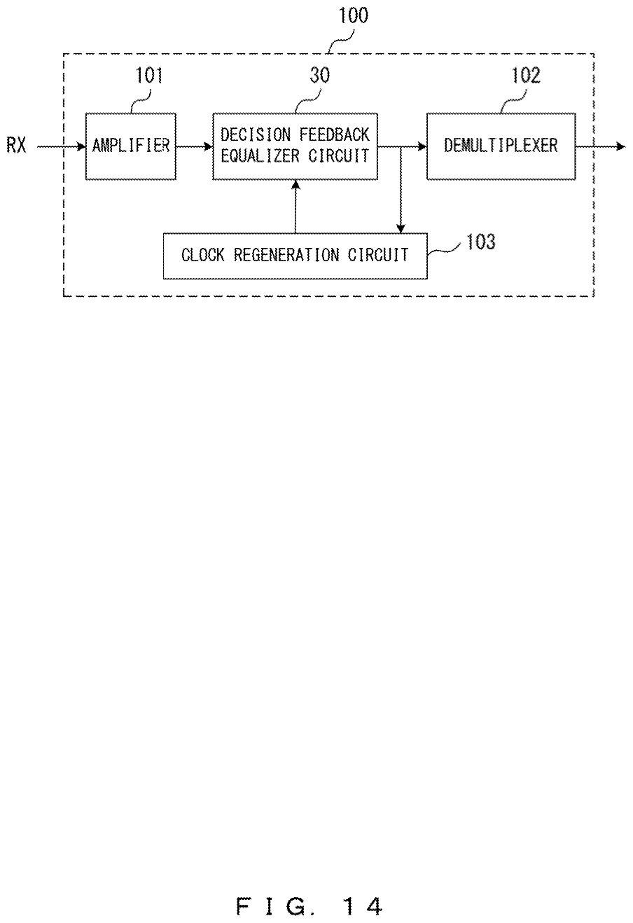

FIG. 14 illustrates an example of a semiconductor integrated circuit that includes the decision feedback equalizer circuit (DFE) 30. In this example, a semiconductor integrated circuit 100 may be equipped with a receiver circuit that converts an input serial signal RK to a parallel signal.

The receiver circuit includes a differential amplifier 101, the decision feedback equalizer circuit 30, a demultiplexer 102, and a clock regeneration circuit 103. The differential amplifier 101 amplifies a differential serial signal RX transmitted via a communication path or the The decision feedback equalizer circuit 30 performs decision for each symbol of the input serial signal. The demultiplexer 102 performs serial/parallel conversion for the output signal of the decision feedback equalizer circuit 30. Meanwhile, the parallel data signal that is output from the demultiplexer 102 is guided to a signal processing circuit that is not illustrated in the drawing. The clock regeneration circuit 103 regenerates a clock signal to be provided to the decision feedback equalizer circuit 30, according to the signal that is output from the decision feedback equalizer circuit 30.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present inventions have been described in detail, it should be understood that the various changes, substitutions, and alterations could be made hereto without departing from the spirit and scope of the invention.

What is claimed is:

1. A decision feedback equalizer circuit that equalizes a differential signal using a first equalizer circuit and a second equalizer circuit implemented in parallel, wherein
each of the first equalizer circuit and the second equalizer circuit includes:
an adder circuit; and
a comparator configured to alternatingly perform refreshing and sampling for a differential signal output from the adder circuit in response to a clock signal, and
the respective comparator includes:
a differential amplifier circuit configured to output a differential signal having same values in a refresh period in which the refreshing is performed, and output a differential signal corresponding to the differential signal output from the adder circuit in a sampling period in which the sampling is performed; and
a latch circuit configured to perform a decision operation based on a comparison between a first signal and a second signal that form the differential signal output from the differential amplifier circuit in the sampling period, and to latch a decision result of the decision operation, and
the adder circuit in the first equalizer circuit controls a differential signal input to the decision feedback equalizer circuit based on the decision result latched by the latch circuit in the second equalizer circuit, and
the adder circuit in the second equalizer circuit controls the differential signal input to the decision feedback equalizer circuit based on the decision result latched by the latch circuit in the first equalizer circuit.

2. The decision feedback equalizer circuit according to claim 1 further comprising a duty cycle adjustment circuit configured to adjust a duty ratio of the clock signal, wherein
each of the differential amplifier circuits configured to perform the refreshing operation when the clock signal is in a first state and to perform the sampling operation when the clock signal is in a second state, and
the duty cycle adjustment circuit generates a duty-adjusted clock signal by adjusting a duty ratio of the clock signal so that the sampling period is longer than the refresh period.

3. The decision feedback equalizer circuit according claim 2, wherein
the duty-adjusted clock signal is given to the first equalizer circuit and the second equalizer circuit so that the sampling period starts in the second equalizer circuit before the sampling period ends in the first equalizer circuit, and the sampling period starts in the first equalizer circuit before the sampling period ends in the second equalizer circuit.

4. The decision feedback equalizer circuit according claim 3, wherein
a timing of the duty-adjusted clock signal is adjusted so that, in the comparator of the first equalizer circuit, a timing of a change of the duty-adjusted clock signal from the first state to the second state appears approximately at a center of an even-numbered symbol of the input differential signal of the decision feedback equalizer circuit, and in the comparator of the second equalizer circuit, a timing of a change of the duty-adjusted clock signal from the first state to the second state appears approximately at a center of an odd numbered symbol of the input differential signal of the decision feedback equalizer circuit.

5. The decision feedback equalizer circuit according claim 2, wherein
the respective differential amplifier circuit is equipped with a first short circuit that electrically shorts a pair of output lines of the corresponding differential amplifier circuit at a start of the refresh period.

6. The decision feedback equalizer circuit according claim 2, wherein
the respective latch circuit is equipped with a second short circuit that electrically shorts a pair of output lines of the corresponding latch circuit at a start of the refresh period.

7. A semiconductor integrated circuit comprising:
a decision feedback equalizer circuit that equalizes a differential signal using a first equalizer circuit and a second equalizer circuit implemented in parallel;
a demultiplexer that performs serial/parallel conversion for an output signal of the decision feedback equalizer circuit; and
a clock regeneration circuit that regenerates a clock signal from the output signal of the decision feedback equalizer circuit, wherein
each of the first equalizer circuit and the second equalizer circuit includes:
an adder circuit; and
a comparator configured to alternatingly perform refreshing and sampling for a differential signal output from the adder circuit in response to the clock signal, and
the respective comparator includes:
a differential amplifier circuit configured to output a differential signal having same values in a refresh period in which the refreshing is performed, and output a differential signal corresponding to the differential signal output from the adder circuit in a sampling period in which the sampling performed; and
a latch circuit configured to perform a decision operation based on a comparison between a first signal and a second signal that form the differential signal output from the adder circuit in the sampling period, and to latch a decision result of the decision operation, and
the adder circuit in the first equalizer circuit controls the differential signal input to the decision feedback equalizer circuit based on the decision result latched by the latch circuit in the second equalizer circuit, and
the adder circuit in the second equalizer circuit controls the differential signal input to the decision feedback equalizer circuit based on the decision result latched by the latch circuit in the first equalizer circuit.
